(19) United States
(12) Patent Application Publication
(10) Pub. No.: US 2024/0150380 A1
(43) Pub. Date: May 9, 2024

(54) SILANE PRECURSORS AND RELATED METHODS

(71) Applicant: ENTEGRIS, INC., Billerica, MA (US)

(72) Inventors: MinSeok Ryu, Namdong-gu (KR); SangJin Lee, Suwon-si (KR); YeRim Yeon, Suwon-si (KR); SeongCheol Kim, Suwon-si (KR); KieJin Park, Gwacheon-si (KR)

(21) Appl. No.: 18/381,282

(22) Filed: Oct. 18, 2023

Related U.S. Application Data
(60) Provisional application No. 63/528,815, filed on Jul. 25, 2023.
(60) Provisional application No. 63/417,620, filed on Oct. 19, 2022.

(51) Int. Cl. C07F 7/02

(52) U.S. Cl. CPC C07F 7/025

(57) ABSTRACT

Silane precursors and related methods are provided. A method for preparing a silane precursor may comprise one or more of the following steps: contacting a dihalide silane compound and an amine in a first solvent to obtain a first reaction product; and contacting the first reaction product and a reductant in a second solvent to obtain a second reaction product.

### FIELD

The present disclosure relates to silane precursors for vapor deposition processes and related methods.

### BACKGROUND

Vapor deposition processes use precursors. Precursors are vaporized and deposited on substrates as films.

### SUMMARY

Some embodiments of the present disclosure relate to a precursor. In some embodiments, the precursor comprises a compound of the formula:

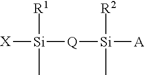

wherein:
X is F, Cl, Br, or I;
R¹ and R² are each independently a hydrogen, an alkyl, an alkenyl, an alkynyl, a cycloalkyl, an aryl, or a benzyl;
A is an amine;
Q is a bond or —SiR³R⁴—,
wherein R³ and R⁴ are each independently a hydrogen, an alkyl, an alkenyl, an alkynyl, a cycloalkyl, an aryl, or a benzyl.

Some embodiments of the present disclosure relate to a precursor. In some embodiments, the precursor comprises a compound of the formula:

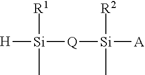

wherein:
R¹ and R² are each independently a hydrogen, an alkyl, an alkenyl, an alkynyl, a cycloalkyl, an aryl, or a benzyl;
A is an amine;
Q is a bond or —SiR³R⁴—,
wherein R³ and R⁴ are each independently a hydrogen, an alkyl, an alkenyl, an alkynyl, a cycloalkyl, an aryl, or a benzyl.

Some embodiments of the present disclosure relate to a method for forming a precursor. In some embodiments, the method comprises one or more of the following steps: contacting a dihalide silane compound and an amine in a first solvent to obtain a first reaction product, and contacting the first reaction product and a reductant in a second solvent to obtain a second reaction product.

Some embodiments of the present disclosure relate to a method for vapor deposition. In some embodiments, the method for vapor deposition comprises one or more of the following steps: obtaining a precursor; vaporizing the precursor to obtain a vaporized precursor; and contacting the vaporized precursor with a substrate, under vapor deposition conditions, to form a silicon-containing film on the substrate.

Some embodiments of the present disclosure relate to an article. In some embodiments, the article comprises a substrate, and a silicon-containing film on a surface of the substrate.

### BRIEF DESCRIPTION OF THE DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a flowchart of a method for preparing silane precursors, according to

some embodiments.

FIG. 2 is a flowchart of a method for making a silicon-containing film, according to some embodiments.

FIG. 3 is a schematic diagram of a silicon-containing film on a surface of a substrate, according to some embodiments.

FIG. 4 is a ¹H NMR spectra for N-Ethyl-N-methyl (1,1,2,2-tetramethyldisilanyl) amine, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “alkyl” refers to a hydrocarbon chain radical having from 1 to 30 carbon atoms. The alkyl may be attached via a single bond. An alkyl having n carbon atoms may be designated as a “Cn alkyl.” For example, a “C3 alkyl” may include n-propyl and isopropyl. An alkyl having a range of carbon atoms, such as 1 to 30 carbon atoms, may be designated as a Ci-C30 alkyl. In some embodiments, the alkyl is linear. In some embodiments, the alkyl is branched. In some embodiments, the alkyl is substituted. In some embodiments, the alkyl is unsubstituted. In some embodiments, the alkyl may comprise, consist of, or consist essentially of, or may be selected from the group consisting of, at least one of a C₁-C₁₂ alkyl, a C₁-C₁₁ alkyl, a C₁-C₁₀ alkyl, a C₁-C₉ alkyl, a C₁-C₈ alkyl, a C₁-C₇ alkyl, a C₁-C₆ alkyl, a C₁-C₅ alkyl, a C₁-C₄ alkyl, a C₁-C₃ alkyl, a C₂-C₁₀ alkyl, a C₃-C₁₀ alkyl, a C₄-C₁₀ alkyl, a C₅-C₁₀ alkyl, a C₆-C₁₀ alkyl, a C₇-C₁₀ alkyl, a C₈-C₁₀ alkyl, a C₂-C₉ alkyl, a C₂-C₈ alkyl, a C₂-C₇ alkyl, a C₂-C₆ alkyl, a C₂-C₅ alkyl, a C₃-C₅ alkyl, a C₃-C₄ alkyl, or any combination thereof. In some embodiments, the alkyl may comprise, consist of, or consist essentially of, or may be selected from the group consisting of, at least one of methyl, ethyl, n-propyl, 1-methylethyl (iso-propyl), n-butyl, iso-butyl, sec-butyl, n-pentyl, 1,1-dimethylethyl (t-butyl), n-pentyl, iso-pentyl, n-hexyl, isohexyl, 3-methylhexyl, 2-methylhexyl, octyl, decyl, dodecyl, octadecyl, or any combination thereof. In some embodiments, the alkyl is substituted with one or more substituents.

As used herein, the term “alkenyl” refers to a hydrocarbon chain radical having from 1 to 10 carbon atoms and at least one carbon-carbon double bond. Examples of alkenyl groups include, without limitation, at least one of vinyl, allyl, 1-methylvinyl, 1-propenyl, 1-butenyl, 2-butenyl, 3-butenyl, 1,3-butadienyl, 2-methyl-1-propenyl, 2-methyl-2-propenyl, 1-pentenyl, 2-pentenyl, 3-pentenyl, 4-pentenyl, 1,3-pentadienyl, 2,4-pentadienyl, 1,4-pentadienyl, 3-methyl-2-butenyl, 1-hexenyl, 2-hexenyl, 3-hexenyl, 1,3-hexadienyl, 1,4-hexadienyl, 2-methylpentenyl, 1-heptenyl, 3-heptenyl, 1-octenyl, 1,3-octadienyl, 1-nonenyl, 2-nonenyl, 3-nonenyl, 1-decenyl, 3-decenyl, 1-undecenyl, oleyl, linoleyl, linolenyl, or any combination thereof. In some embodiments, the alkenyl is substituted with one or more substituents.

As used herein, the term “alkynyl” refers to a hydrocarbon chain radical having from 1 to 10 carbon atoms and at least one carbon-carbon triple bond. Examples of alkynyl groups include, without limitation, at least one of ethynyl, propynyl, n-butynyl, n-pentynyl, 3-methyl-1-butynyl, n-hexynyl, methyl-pentynyl, or any combination thereof. In some embodiments, the alkynyl is substituted with one or more substituents.

As used herein, the term “cycloalkyl” refers to a non-aromatic carbocyclic ring radical attached via a single bond and having from 3 to 8 carbon atoms in the ring. In some embodiments, the cycloalkyl comprises a C₃-C₆ cycloalkyl. The term includes a monocyclic non-aromatic carbocyclic ring and a polycyclic non-aromatic carbocyclic ring. For example, two or more cycloalkyls may be fused, bridged, or fused and bridged to obtain the polycyclic non-aromatic carbocyclic ring. In some embodiments, the cycloalkyl may comprise, consist of, or consist essentially of, or may be selected from the group consisting of, at least one of cyclopropyl, cyclobutyl, cyclopentyl, cyclohexyl, cycloheptyl, cyclooctyl, or any combination thereof. In some embodiments, the cycloalkyl is substituted with one or more substituents. As used herein, the term “aryl” refers to a monocyclic or polycyclic aromatic

hydrocarbon radical. The number of carbon atoms of the aryl may be in a range of 5 carbon atoms to 20 carbon atoms. For example, in some embodiments, the aryl has 6 to 8 carbon atoms, 6 to 10 carbon atoms, 6 to 12 carbon atoms, 6 to 15 carbon atoms, or 6 to 20 carbon atoms. The term “monocyclic,” when used as a modifier, refers to an aryl having a single aromatic ring structure. The term “polycyclic,” when used as a modifier, refers to an aryl having more than one aromatic ring structure, which may be fused, bridged, spiro, or otherwise bonded ring structures. Examples of aryls include, without limitation, phenyl, biphenyl, napthyl, and the like. In some embodiments, the aryl is substituted with one or more substituents.

Non-limiting examples of aryl include, without limitation, at least one of benzene, toluene, xylene (e.g., o-xylene, m-xylene, p-xylene), t-butyltoluene (e.g., o-t-butyltoluene, m-t-butyltoluene, p-t-butyltoluene), ethylmethylbenzene (e.g., 1-ethyl-4-methylbenzene, 1-ethyl-3-methylbenzene), 1-isopropyl-4-methylbenzene, 1-t-butyl-4-methylbenzene, mesitylene, pseudocumene, durene, methylbenzene, dimethylbenzene, trimethylbenzene, ethylbenzene, diethylbenzene (e.g., 1,4-diethylbenzene), triethylbenzene, propylbenzene, butylbenzene, iso-butylbenzene, sec-butylbenzene, t-butylbenzene, hexylbenzene, styrene, naphthalene, anthracene, phenanthrene, biphenyl, terphenyl, methylnaphthalene, biphenylene, dimethylnaphthalene, methylanthracene, 4,4′-dimethylbiphenyl, bibenzyl, diphenylmethane, any isomer thereof, or any combination thereof, and the like.

As used herein, the term “amine” refers to a radical of formula —N(R^{a}R^{b}R^{c}), wherein each of R^{a}, R^{b}, and R^{c} is independently a hydrogen, an alkyl, an alkenyl, an alkynyl, a cycloalkyl, an aryl, or a benzyl, or two of R^{a}, R^{b}, and R^{c} are bonded to form a 3-membered cyclic ring to a 6-membered cyclic ring. In some embodiments, where at least one of R^{a}, R^{b}, and R^{c} is a hydrogen, the amine is a radical of the formula: —NH(R^{b}R^{c}). In some embodiments, the term “amine” includes an amino, as defined herein. In some embodiments, the amine may comprise, consist of, or consist essentially of a primary amine, a secondary amine, a tertiary amine, or a quaternary amine. In some embodiments, the amine may comprise, consist of, or consist essentially of an alkyl amine, a dialkylamine, or a trialkyl amine. In some embodiments, the amine may comprise, consist of, or consist essentially of, or may be selected from the group consisting of, at least one of methyl amine, dimethylamine, ethylamine, diethylamine, isopropylamine, di-isopropylamine, butylamine, sec-butylamine, tert-butylamine, di-sec-butylamine, isobutylamine, di-isobutylamine, di-tert-pentylamine, ethylmethylamine, isopropyl-n-propylamine, or any combination thereof. Examples of the amines may include, without limitation, one or more of the following: primary amines, such as, for example and without limitation, methylamine, ethylamine, n-propylamine, isopropylamine, n-butylamine, sec-butylamine, isobutylamine, t-butylamine, pentylamine, 2-aminopentane, 3-aminopentane, 1-amino-2-methylbutane, 2-amino-2-methylbutane, 3-amino-2-methylbutane, 4-amino-2-methylbutane, hexylamine, 5-amino-2-methylpentane, heptylamine, octylamine, nonylamine, decylamine, undecylamine, dodecylamine, tridecylamine, tetradecylamine, pentadecylamine, hexadecylamine, heptadecylamine, and octadecylamine; secondary amines, such as, for example and without limitation, dimethylamine, diethylamine, dipropylamine, diisopropylamine, dibutylamine, diisobutylamine, di-sec-butylamine, di-t-butylamine, dipentylamine, dihexylamine, diheptylamine, dioctylamine, dinonylamine, didecylamine, methylethylamine, methylpropylamine, methylisopropylamine, methylbutylamine, methylisobutylamine, methyl-sec-butylamine, methyl-t-butylamine, methylamylamine, methylisoamylamine, ethylpropylamine, ethylisopropylamine, ethylbutylamine, ethylisobutylamine, ethyl-sec-butylamine, ethylamine, ethylisoamylamine, propylbutylamine, and propylisobutylamine; and tertiary amines, such as, for example and without limitation, trimethylamine, triethylamine, tripropylamine, tributylamine, tripentylamine, dimethylethylamine, methyldiethylamine, and methyldipropylamine. Examples of polyamines may include, without limitation, one or more of the following: ethylenediamine, propylenediamine, trimethylenediamine, tetramethylenediamine, 1,3-diaminobutane, 2,3-diaminobutane, pentamethylenediamine, 2,4-diaminopentane, hexamethylenediamine, heptamethylenediamine, octamethylenediamine, nonamethylenediamine, N-methylethylenediamine, N,N-dimethylethylenediamine, trimethylethylenediamine, N-ethylethylenediamine, N,N-diethylethylenediamine, triethylethylenediamine, 1,2,3-triaminopropane, hydrazine, tris(2-aminoethyl)amine, tetra(aminomethyl)methane, diethylenetriamine, triethylenetetramine, tetraethylpentamine, heptaethyleneoctamine, nonaethylenedecamine, and diazabicyloundecene. In some embodiments, the amine is substituted with one or more substituents.

In some embodiments, the polyamine compound comprises, consists of, or consists essentially of, or is selected from the group consisting of, at least one of ethylenediamine, propylenediamine, trimethylenediamine, triethylenediamine, methylpentanediamine, tetramethylenediamine, 1,3-diaminobutane, 2,3-diaminobutane, pentamethylenediamine, 2,4-diaminopentane, hexamethylenediamine, heptamethylenediamine, octamethylenediamine, nonamethylenediamine, 1,2,3-triaminopropane, hydrazine, tetra(aminomethyl)methane, or any combination thereof. In some embodiments, the polyamine compound comprises, consists of, consists essentially of, or is selected from the group consisting of, at least one of N-methylethylenediamine, N,N-dimethylethylenediamine, trimethylethylenediamine, N-ethylethylenediamine, N,N-diethylethylenediamine, triethylethylenediamine, or any combination thereof. In some embodiments, the polyamine compound comprises, consists of, consists essentially of, or is selected from the group consisting of, at least one of tris(2-aminoethyl)amine, diethylenetriamine, triethylenetetramine, tetraethylenepentamine, heptaethyleneoctamine, nonaethylenedecamine, N′,N′-bis(2-aminoethyl)ethane-1,2-diamine, or any combination thereof. In some embodiments, the polyamine compound comprises at least one of 1,2-ethane diamine; 1,2-propane diamine; 1,3-propane diamine; 1,4-butane diamine; 1,6-hexane diamine; 2-methyl-1,5-pentane diamine; 2,2(4),4-trimethylhexanediamine; 2,2,4-trimethyl-1,6-hexanediamine; 2,4,4-trimethyl-1,6-hexanediamine; or any combination thereof.

As used herein, the term “silicon-containing film” refers to a film comprising at least one of silicon, silicon nitride, silicon oxynitride, silicon oxide, silicon dioxide, silicon carbide, silicon carbonitride, silicon oxycarbonitride, carbon-doped silicon nitride, carbon-doped silicon oxide, carbon-doped silicon oxynitride, or any combination thereof. For example, the silicon-containing film may comprise at least one of a SiO film, a SiN film, a SiOC film, a SiCN film, a SiOCN film, or any combination thereof. In some embodiments, the silicon-containing film has a thickness of 20 Å to 2000 Å.

Some embodiments relate to silane precursors and related methods. At least some of these embodiments relate to silane precursors useful in the fabrication of microelectronic devices, including semiconductor devices, and the like. For example, the silane precursors can be used to form silicon-containing films by one or more deposition processes. Examples of deposition processes include, without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof. Silane precursors, such as, for example and without limitation, amino-silane (Si—Si) derivatives useful for thin film deposition are provided. The silane precursors disclosed herein may be present in a liquid state at room temperature and atmospheric pressure. The silane precursors disclosed herein may exhibit superior volatility and enhanced reactivity relative to conventional precursors. The silane precursors thus may exhibit improvements with respect to the ease with which thin films may be formed. In some embodiments, the amino-silane precursor comprises a Si—N bond exhibiting excellent surface reactivity so as to result in enhanced surface cohesion. In some embodiments, the presence of multiple Si atoms results in improved growth deposition rates as compared to precursors having only a single Si atom. The silane precursors disclosed herein may be useful in the formation of silicon-containing films, such as, for example and without limitation, SiO, SiN, SiOC, SiCN, SiOCN, and the like at low temperatures.

Some embodiments relate to a silane precursor comprising a compound of the formula:

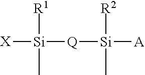

wherein:
X is F, Cl, Br, or I;
R¹ and R² are each independently a hydrogen, an alkyl, an alkenyl, an alkynyl, a cycloalkyl, an aryl, or a benzyl;
A is an amine;
Q is a bond or —SiR³R⁴—,
wherein R³ and R⁴ are each independently a hydrogen, an alkyl, an alkenyl, an alkynyl, a cycloalkyl, an aryl, or a benzyl.

In some embodiments, R¹ and R² are the same. In some embodiments, R¹ and R² are different.

In some embodiments, R³ and R⁴ are the same. In some embodiments, R³ and R⁴ are different.

In some embodiments, the A is an amine. In some embodiments, the A is an amine of the formula:

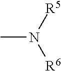

wherein:
R⁵ and R⁶ are each independently a hydrogen, an alkyl, an alkenyl, an alkynyl, a cycloalkyl, an aryl, or a benzyl; or
R⁵ and R⁶ are bonded to obtain a 3-membered cyclic ring to a 6-membered cyclic ring.

In some embodiments, R⁵ and R⁶ are the same. In some embodiments, R⁵ and R⁶ are different.

Examples of the silane precursor include, without limitation, compounds having at least one of the following structures:

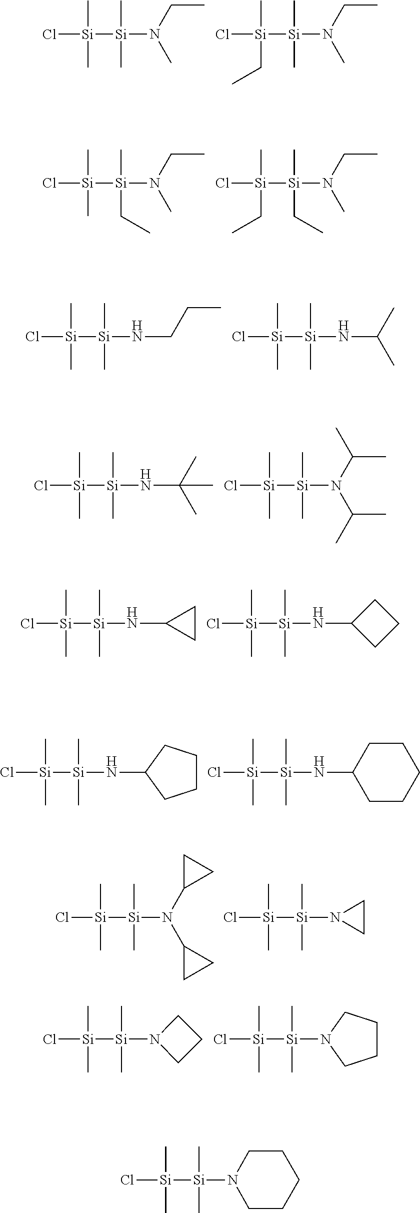

Some embodiments relate to a silane precursor comprising a compound of the formula:

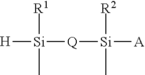

wherein:
R¹ and R² are each independently a hydrogen, an alkyl, an alkenyl, an alkynyl, a cycloalkyl, an aryl, or a benzyl;
A is an amine;
Q is a bond or —SiR³R⁴—,
wherein R³ and R⁴ are each independently a hydrogen, an alkyl, an alkenyl, an alkynyl, a cycloalkyl, an aryl, or a benzyl.

In some embodiments, R¹ and R² are the same. In some embodiments, R¹ and R² are different.

In some embodiments, R³ and R⁴ are the same. In some embodiments, R³ and R⁴ are different.

In some embodiments, the A is an amine. In some embodiments, the A is an amine of the formula:

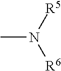

wherein:
R⁵ and R⁶ are each independently a hydrogen, an alkyl, an alkenyl, an alkynyl, a cycloalkyl, an aryl, or a benzyl; or
R⁵ and R⁶ are bonded to obtain a 3-membered cyclic ring to a 6-membered cyclic ring.

In some embodiments, R⁵ and R⁶ are the same. In some embodiments, R⁵ and R⁶ are different.

In some embodiments, the precursor does not comprise a halide. For example, in some embodiments, the precursor does not comprise at least one of F, Cl, Br, or I.

In some embodiments, the precursor is a liquid at a temperature of 20° C. to 30° C. In some embodiments, the precursor is a liquid at atmospheric pressure.

Examples of the silane precursors include, without limitation, compounds having at least one of the following structures:

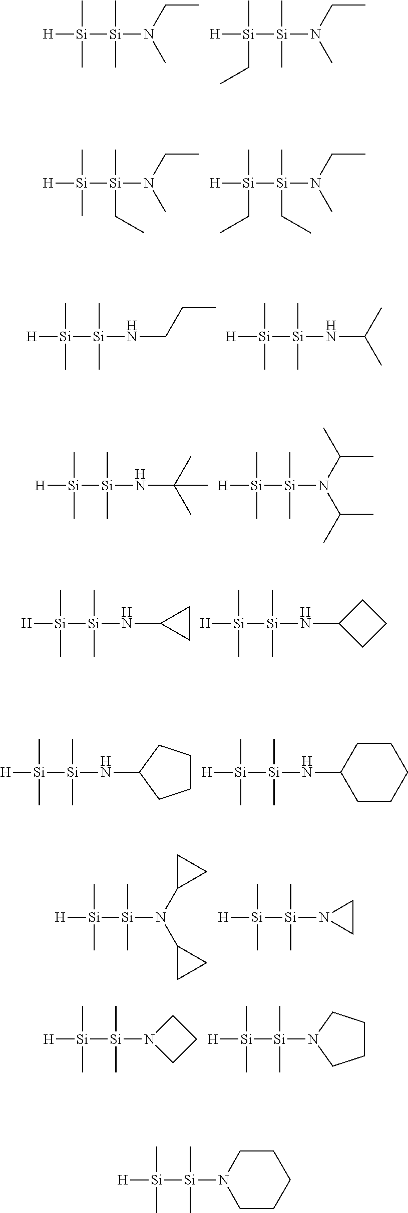

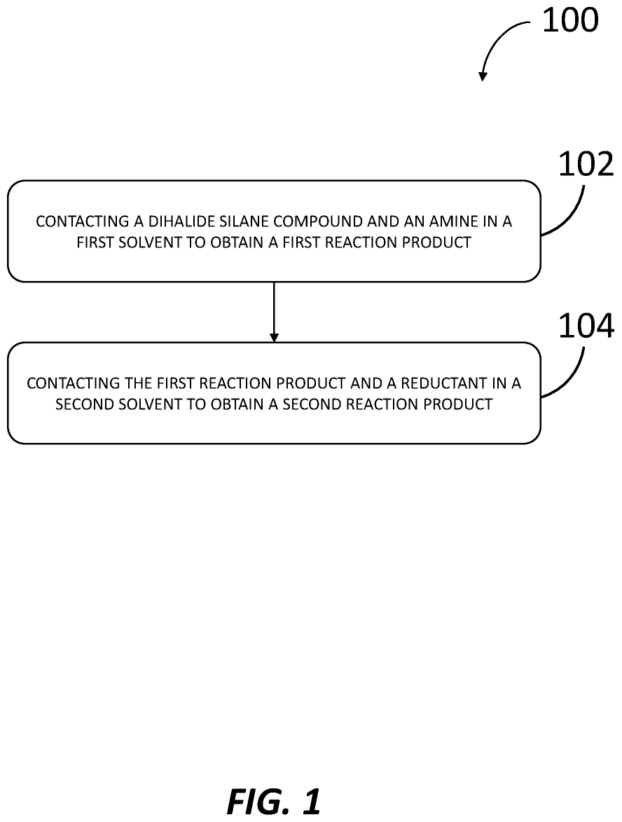

FIG. 1 is a flowchart of a method for preparing silane precursors 100, according to some embodiments. As shown in FIG. 1, the method for preparing silane precursors 100 may comprise one or more of the following steps: a step 102 of contacting a dihalide silane compound and an amine in a first solvent to obtain a first reaction product; and a step 104 of contacting the first reaction product and a reductant in a second solvent to obtain a second reaction product.

At step 102, in some embodiments, the method 100 comprises contacting a dihalide silane compound and an amine in a first solvent to obtain a first reaction product.

In some embodiments, the dihalide silane compound comprises a compound of the formula:

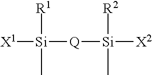

where:
X¹ and X² are each independently F, Cl, Br, or I;
R¹ and R² are each independently a hydrogen, an alkyl, an alkenyl, an alkynyl, a cycloalkyl, an aryl, or a benzyl;
Q is a bond or —SiR³R⁴—,
wherein R³ and R⁴ are each independently a hydrogen, an alkyl, an alkenyl, an alkynyl, a cycloalkyl, an aryl, or a benzyl.

In some embodiments, X¹ and X² are the same. In some embodiments, X¹ and X² are different.

In some embodiments, R¹ and R² are the same. In some embodiments, R¹ and R² are different.

In some embodiments, R³ and R⁴ are the same. In some embodiments, R³ and R⁴ are different.

In some embodiments, the amine is a substituted amine. In some embodiments, the amine is a compound of the formula:

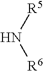

wherein:
R⁵ and R⁶ are each independently a hydrogen, an alkyl, an alkenyl, an alkynyl, a cycloalkyl, an aryl, or a benzyl; or
R⁵ and R⁶ are bonded to obtain a 3-membered cyclic ring to a 6-membered cyclic ring.

In some embodiments, R⁵ and R⁶ are the same. In some embodiments, R⁵ and R⁶ are different.

In some embodiments, the first solvent comprises at least one of dichloromethane (CH₂Cl₂), diethyl ether (Et₂O), n-hexane, ethyl acetate (EtOAc), tetrahydrofuran (THF), or any combination thereof.

In some embodiments, the first reaction product comprises a compound of the formula:

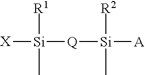

wherein:
X is F, Cl, Br, or I;
R¹ and R² are each independently a hydrogen, an alkyl, an alkenyl, an alkynyl, a cycloalkyl, an aryl, or a benzyl;
A is an amine;
Q is a bond or —SiR³R⁴—,
wherein R³ and R⁴ are each independently a hydrogen, an alkyl, an alkenyl, an alkynyl, a cycloalkyl, an aryl, or a benzyl.

In some embodiments, R¹ and R² are the same. In some embodiments, R¹ and R² are different.

In some embodiments, R³ and R⁴ are the same. In some embodiments, R³ and R⁴ are different.

In some embodiments, the A is an amine. In some embodiments, the A is an amine of the formula:

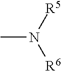

wherein:
R⁵ and R⁶ are each independently a hydrogen, an alkyl, an alkenyl, an alkynyl, a cycloalkyl, an aryl, or a benzyl; or
R⁵ and R⁶ are bonded to obtain a 3-membered cyclic ring to a 6-membered cyclic ring.

In some embodiments, R⁵ and R⁶ are the same. In some embodiments, R⁵ and R⁶ are different.

At step 104, in some embodiments, the method 100 comprises contacting the first reaction product and a reductant in a second solvent to obtain a second reaction product.

In some embodiments, the reductant comprises at least one of LiAlH₄, NaAlH₄, LiH, DiBAL, LiBH₄, NaBH₄, or any combination thereof.

In some embodiments, the second solvent comprises at least one of dichloromethane (CH₂Cl₂), diethyl ether (Et₂O), n-hexane, ethyl acetate (EtOAc), tetrahydrofuran (THF), or any combination thereof.

In some embodiments, the second reaction product comprises a compound of the formula:

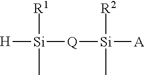

wherein:
R¹ and R² are each independently a hydrogen, an alkyl, an alkenyl, an alkynyl, a cycloalkyl, an aryl, or a benzyl;
A is an amine;
Q is a bond or —SiR³R⁴—,
wherein R³ and R⁴ are each independently a hydrogen, an alkyl, an alkenyl, an alkynyl, a cycloalkyl, an aryl, or a benzyl.

In some embodiments, R¹ and R² are the same. In some embodiments, R¹ and R² are different.

In some embodiments, R³ and R⁴ are the same. In some embodiments, R³ and R⁴ are different.

In some embodiments, the A is an amine. In some embodiments, the A is an amine of the formula:

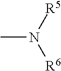

where:
R⁵ and R⁶ are each independently a hydrogen, an alkyl, an alkenyl, an alkynyl, a cycloalkyl, an aryl, or a benzyl; or
R⁵ and R⁶ are bonded to obtain a 3-membered cyclic ring to a 6-membered cyclic ring.

In some embodiments, R⁵ and R⁶ are the same. In some embodiments, R⁵ and R⁶ are different.

In some embodiments, the method for preparing a silane precursor 100 proceeds according to the reaction scheme below:

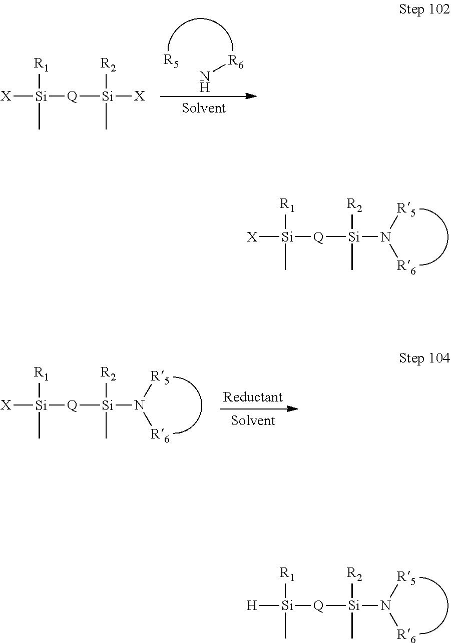

In some embodiments, the method for preparing a silane precursor 100 proceeds according to the reaction scheme below:

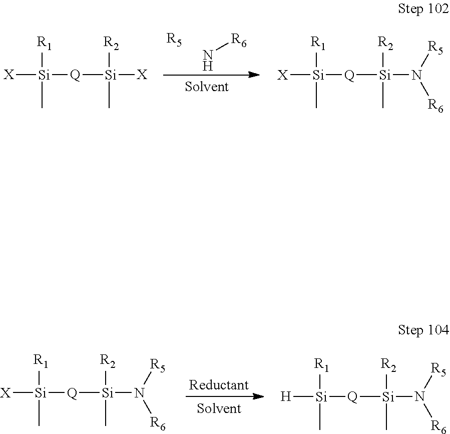

In some embodiments, the method for preparing a disalne precursor 100 with oxygen proceeds according to the reaction scheme below, wherein the R1 can be methyl, ethyl or any alkyl group:

[symbol]

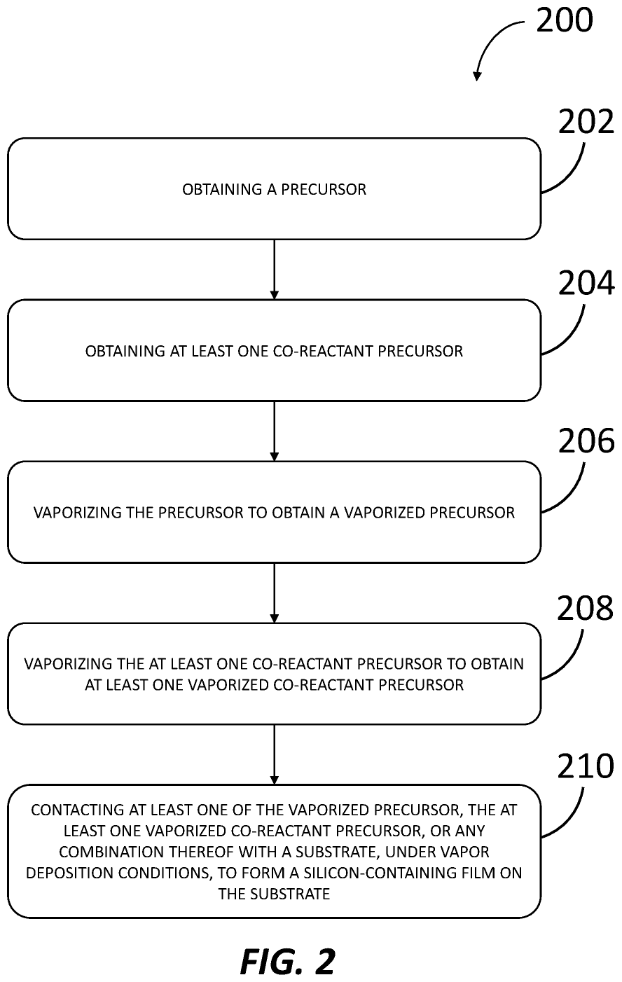

FIG. 2 is a flowchart of a method for making a silicon-containing film 200, according to some embodiments. As shown in FIG. 2, the method for making a silicon-containing film 200 may comprise, consist of, or consist essentially of one or more of the following steps: obtaining 202 a precursor, obtaining 204 at least one co-reactant precursor, vaporizing 206 the precursor to obtain a vaporized precursor, vaporizing 208 the at least one co-reactant precursor to obtain at least one vaporized co-reactant precursor, contacting 210 at least one of the vaporized precursor, the at least one vaporized co-reactant precursor, or any combination thereof with a substrate, under vapor deposition conditions, to form a silicon-containing film on the substrate.

The step 202 may comprise, consist of, or consist essentially of obtaining a precursor. The precursor may comprise, consist of, or consist essentially of any one or more of the precursors disclosed herein. The obtaining may comprise obtaining a container or other vessel comprising the precursor. In some embodiments, the precursor may be obtained in a container or other vessel in which the precursor is to be vaporized.

The step 204 may comprise, consist of, or consist essentially of obtaining at least one co-reactant precursor. In some embodiments, the at least one co-reactant precursor comprises, consists of, or consists essentially of, or is selected from the group consisting of, at least one of an oxidizing gas, a reducing gas, a hydrocarbon, or any combination thereof. The at least one co-reactant precursor may be selected to obtain a desired silicon-containing film. In some embodiments, the at least one co-reactant precursor may comprise, consist of, or consist essentially of at least one of N₂, H₂, NH₃, N₂H₄, CH₃HNNH₂, CH₃HNNHCH₃, NCH₃H₂, NCH₃CH₂H₂, N(CH₃)₂H, N(CH₃CH₂)₂H, N(CH₃)₃, N(CH₃CH₂)₃, Si(CH₃)₂NH, pyrazoline, pyridine, ethylene diamine, a radical thereof, or any combination thereof. In some embodiments, the at least one co-reactant precursor may comprise, consist of, or consist essentially of at least one of H₂, O₂, O₃, H₂O, O₂, NO, N₂O, NO₂, CO, CO₂, a carboxylic acid, an alcohol, a diol, a radical thereof, or any combination thereof. In some embodiments, the at least one co-reactant precursor comprise, consist of, or consist essentially of at least one of methane, ethane, ethylene, acetylene, or any combination thereof. The obtaining may comprise obtaining a container or other vessel comprising the at least one co-reactant precursor. In some embodiments, the at least one co-reactant precursor may be obtained in a container or other vessel in which the at least one co-reactant precursor is to be vaporized. In some embodiments, the method further comprises an inert gas, such as, for example, at least one of argon, helium, nitrogen, or any combination thereof.

The step 206 may comprise, consist of, or consist essentially of vaporizing the precursor to obtain a vaporized precursor. The vaporizing may comprise, consist of, or consist essentially of heating the precursor sufficient to obtain the vaporized precursor. In some embodiments, the vaporizing may comprise, consist of, or consist essentially of heating a container comprising the precursor. In some embodiments, the vaporizing may comprise, consist of, or consist essentially of heating the precursor in a deposition chamber in which the vapor deposition process is performed. In some embodiments, the vaporizing may comprise, consist of, or consist essentially of heating a conduit for delivering the precursor, vaporized precursor, or any combination thereof to, for example, a deposition chamber. In some embodiments, the vaporizing may comprise, consist of, or consist essentially of operating a vapor delivery system comprising the precursor. In some embodiments, the vaporizing may comprise, consist of, or consist essentially of heating to a temperature sufficient to vaporize the precursor to obtain the vaporized precursor. In some embodiments, the vaporizing may comprise, consist of, or consist essentially of heating to a temperature below a decomposition temperature of at least one of the precursor, the vaporized precursor, or any combination thereof. In some embodiments, the precursor may be present in a gas phase, in which case the step 206 is optional and not required. For example, the precursor may comprise, consist of, or consist essentially of the vaporized precursor.

The step 208 may comprise, consist of, or consist essentially of vaporizing the at least one co-reactant precursor to obtain the at least one vaporized co-reactant precursor. In some embodiments, the vaporizing may comprise, consist of, or consist essentially of heating the at least one co-reactant precursor sufficient to obtain the at least one vaporized co-reactant precursor. In some embodiments, the vaporizing may comprise, consist of, or consist essentially of heating a container comprising the at least one co-reactant precursor. In some embodiments, the vaporizing may comprise, consist of, or consist essentially of heating the at least one co-reactant precursor in a deposition chamber in which the vapor deposition process is performed. In some embodiments, the vaporizing may comprise, consist of, or consist essentially of heating a conduit for delivering the at least one co-reactant precursor, the at least one vaporized co-reactant precursor, or any combination thereof to, for example, a deposition chamber. In some embodiments, the vaporizing may comprise, consist of, or consist essentially of operating a vapor delivery system comprising the at least one co-reactant precursor. In some embodiments, the vaporizing may comprise, consist of, or consist essentially of heating to a temperature sufficient to vaporize the at least one co-reactant precursor to obtain the at least one vaporized co-reactant precursor. In some embodiments, the vaporizing may comprise, consist of, or consist essentially of heating to a temperature below a decomposition temperature of at least one of the at least one co-reactant precursor, the at least one vaporized co-reactant precursor, or any combination thereof. In some embodiments, the at least one co-reactant precursor may be present in a gas phase, in which case the step 108 is optional and not required. For example, the at least one co-reactant precursor may comprise, consist of, or consist essentially of the at least one vaporized co-reactant precursor.

The step 210 may comprise, consist of, or consist essentially of contacting at least one of the vaporized precursor, the at least one vaporized co-reactant precursor, or any combination thereof, with the substrate, under vapor deposition conditions, sufficient to form a silicon-containing film on a surface of the substrate. The contacting may be performed in any system, apparatus, device, assembly, chamber thereof, or component thereof suitable for vapor deposition processes, including, for example and without limitation, a deposition chamber, among others. The vaporized precursor and the at least one co-reactant precursor may be contacted with the substrate at the same time or at different times. For example, each of the vaporized precursor, the at least one vaporized co-reactant precursor, and the substrate may be present in the deposition chamber at the same time. That is, in some embodiments, the contacting may comprise contemporaneous contacting or simultaneous contacting of the vaporized precursor and the at least one vaporized co-reactant precursor with the substrate. Alternatively, each of the vaporized precursor and the at least one vaporized co-reactant precursor may be present in the deposition chamber at different times. That is, in some embodiments, the contacting may comprise alternate and/or sequential contacting, in one or more cycles, of the vaporized precursor with the substrate and subsequently contacting the at least one vaporized co-reactant precursor with the substrate.

The vapor deposition conditions may comprise conditions for vapor deposition processes. Examples of vapor deposition conditions include, without limitation, vapor deposition conditions for vapor deposition processes including at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

The vapor deposition conditions may comprise, consist of, or consist essentially of a deposition temperature. The deposition temperature may be a temperature less than the thermal decomposition temperature of at least one of the vaporized precursor, the at least one vaporized co-reactant precursor, or any combination thereof. The deposition temperature may be sufficiently high to reduce or avoid condensation of at least one of the vaporized precursor, the at least one vaporized co-reactant precursor, or any combination thereof. In some embodiments, the substrate may be heated to the deposition temperature. In some embodiments, the chamber or other vessel in which the substrate is contacted with the vaporized precursor and the at least one vaporized co-reactant precursor is heated to the deposition temperature. In some embodiments, at least one of the vaporized precursor, the at least one vaporized co-reactant precursor, or any combination thereof may be heated to the deposition temperature.

The deposition temperature may be a temperature of 200° C. to 2500° C. In some embodiments, the deposition temperature may be a temperature of 500° C. to 700° C. For example, in some embodiments, the deposition temperature may be a temperature of 500° C. to 680° C., 500° C. to 660° C., 500° C. to 640° C., 500° C. to 620° C., 500° C. to 600° C., 500° C. to 580° C., 500° C. to 560° C., 500° C. to 540° C., 500° C. to 520° C., 520° C. to 700° C., 540° C. to 700° C., 560° C. to 700° C., 580° C. to 700° C., 600° C. to 700° C., 620° C. to 700° C., 640° C. to 700° C., 660° C. to 700° C., or 680° C. to 700° C. In other embodiments, the deposition temperature may be a temperature of greater than 200° C. to 2500° C., such as, for example and without limitation, a temperature of 400° C. to 2000, 500° C. to 2000° C., 550° C. to 2400° C., 600° C. to 2400° C., 625° C. to 2400° C., 650° C. to 2400° C., 675° C. to 2400° C., 700° C. to 2400° C., 725° C. to 2400° C., 750° C. to 2400° C., 775° C. to 2400° C., 800° C. to 2400° C., 825° C. to 2400° C., 850° C. to 2400° C., 875° C. to 2400° C., 900° C. to 2400° C., 925° C. to 2400° C., 950° C. to 2400° C., 975° C. to 2400° C., 1000° C. to 2400° C., 1025° C. to 2400° C., 1050° C. to 2400° C., 1075° C. to 2400° C., 1100° C. to 2400° C., 1200° C. to 2400° C., 1300° C. to 2400° C., 1400° C. to 2400° C., 1500° C. to 2400° C., 1600° C. to 2400° C., 1700° C. to 2400° C., 1800° C. to 2400° C., 1900° C. to 2400° C., 2000° C. to 2400° C., 2100° C. to 2400° C., 2200° C. to 2400° C., 2300° C. to 2400° C., 500° C. to 2000° C., 500° C. to 1900° C., 500° C. to 1800° C., 500° C. to 1700° C., 500° C. to 1600° C., 500° C. to 1500° C., 500° C. to 1400° C., 500° C. to 1300° C., 500° C. to 1200° C., 500° C. to 1100° C., 500° C. to 1000° C., 500° C. to 1000° C., 500° C. to 900° C., or 500° C. to 800° C.

The vapor deposition conditions may comprise, consist of, or consist essentially of a deposition pressure. In some embodiments, the deposition pressure may comprise, consist of, or consist essentially of a vapor pressure of at least one of the vaporized precursor, the at least one vaporized co-reactant precursor, or any combination thereof. In some embodiments, the deposition pressure may comprise, consist of, or consist essentially of a chamber pressure.

The deposition pressure may be a pressure of 0.001 Torr to 100 Torr. For example, in some embodiments, the deposition pressure may be a pressure of 1 Torr to 30 Torr, 1 Torr to 25 Torr, 1 Torr to 20 Torr, 1 Torr to 15 Torr, 1 Torr to 10 Torr, 5 Torr to 50 Torr, 5 Torr to 40 Torr, 5 Torr to 30 Torr, 5 Torr to 20 Torr, or 5 Torr to 15 Torr. In other embodiments, the deposition pressure may be a pressure of 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, 95 Torr to 100 Torr, 1 Torr to 95 Torr, 1 Torr to 90 Torr, 1 Torr to 85 Torr, 1 Torr to 80 Torr, 1 Torr to 75 Torr, or 1 Torr to 70 Torr. In other further embodiments, the deposition pressure may be a pressure of 1 mTorr to 100 mTorr, 1 mTorr to 90 mTorr, 1 mTorr to 80 mTorr, 1 mTorr to 70 mTorr, 1 mTorr to 60 mTorr, 1 mTorr to 50 mTorr, 1 mTorr to 40 mTorr, 1 mTorr to 30 mTorr, 1 mTorr to 20 mTorr, 1 mTorr to 10 mTorr, 100 mTorr to 300 mTorr, 150 mTorr to 300 mTorr, 200 mTorr to 300 mTorr, or 150 mTorr to 250 mTorr, or 150 mTorr to 225 mTorr.

The substrate may comprise, consist of, or consist essentially of at least one of Si, Co, Cu, Al, W, WN, WC, TiN, Mo, MoC, SiO₂, W, SiN, WCN, Al₂O₃, AlN, ZrO₂, La₂O₃, TaN, RuO₂, IrO₂, Nb₂O₃, Y₂O₃, hafnium oxide, or any combination thereof. In some embodiments, the silicon-containing film may comprise, consist of, or consist essentially of at least one of at least one of silicon, silicon nitride, silicon oxynitride, silicon oxide, silicon dioxide, silicon carbide, silicon carbonitride, silicon oxycarbonitride, carbon-doped silicon nitride, carbon-doped silicon oxide, carbon-doped silicon oxynitride, or any combination thereof. In some embodiments, the substrate may comprise other silicon-based substrates, such as, for example, one or more of polysilicon substrates, metallic substrates, and dielectric substrates.

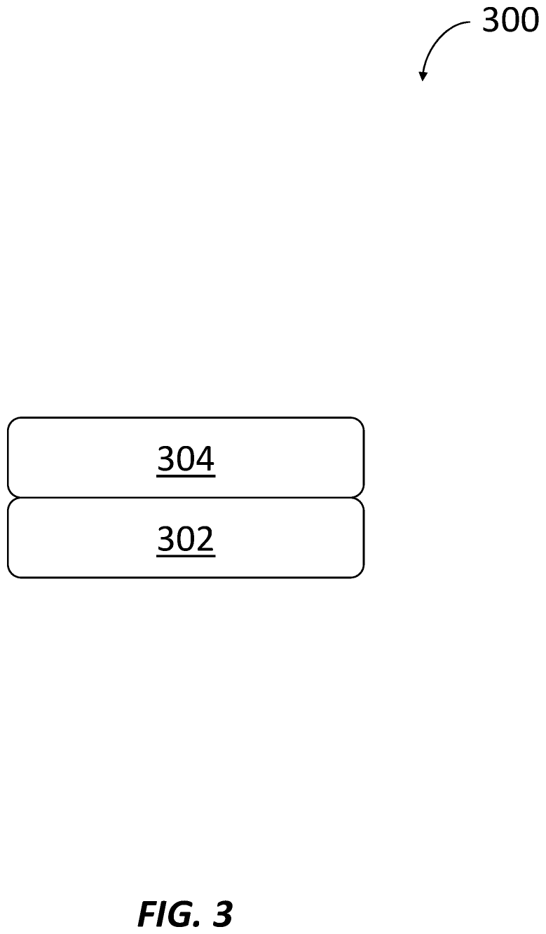

FIG. 3 is a schematic diagram of a silicon-containing film 304 on a surface of a substrate 302, according to some embodiments. In some embodiments, the silicon-containing film 304 comprises any film formed according to the methods disclosed herein. In some embodiments, the silicon-containing film 304 comprises any film prepared from the precursors disclosed herein.

### Example 1

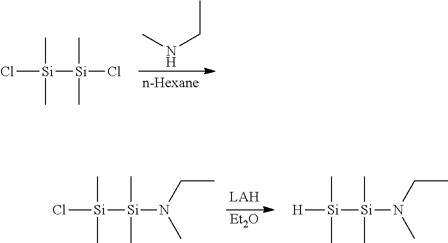

To a flame dried vessel including n-Hexane (1.2 L), 1,2-Dichloro-1,1,2,2-tetramethyldisilane (DCTMDS, 70 g, 0.374 mol) was added. N-Ethyl-N-methylamine (EMA, 46.4 g, 0.785 mol) was subsequently added dropwise for 1 h (inner temperature was maintained under 30° C.). The reaction mixture was stirred at room temperature for 20 hours under N₂ atmosphere. Upon completion of the reaction, a white precipitate resulting from the reaction was filtered through celite pad with n-hexane. The filtrate was concentrated at 50° C. and 150 torr.

The residue(N-Ethyl-N-methyl(2-chloro-1,1,2,2-tetramethyldisilanyl)amine) was dissolved in Et₂O (0.8 L). A 1 M solution of LAH in ether (195 ml, 0.195 mol) was added at 0° C. to the mixture. The reaction was stirred at room temperature for 20 hours. The reaction mixture was filtered through a Celite pad, and the filtrate was concentrated at 40° C. and 200 torr. The final product (N-Ethyl-N-methyl(1,1,2,2-tetramethyldisilanyl)amine) was purified by fractional distillation (41° C. and 3 torr) and resulted in a colorless liquid (30 g, 45.7% yield).

N-Ethyl-N-methyl(1,1,2,2-tetramethyldisilanyl)amine. ¹H NMR (CDCl₃, Hollyhock-1): δ 3.63-3.67 (m, 1 H), δ 2.78 (q, J=0.01 Hz, 2H), 2.46 (s, 3H), δ 1.01 (t, J=0.01 Hz, 3H), 0.15 (s, 6H), 0.13 (d, J =0.009 Hz, 6H) ppm.

N-Ethyl-N-methyl(2-chloro-1,1,2,2-tetramethyldisilanyl)amine. ¹H NMR (CDCl₃, Compound-2): δ 2.78 (q, J=0.014 Hz, 2H), 2.48 (s, 3H), δ 1.01 (t, J=0.014 Hz, 3H), 0.47 (s, 6H), 0.23 (s, 6H) ppm.

Further to Example 1, Example 2 is shown below, using the final product (N-Ethyl-N-methyl(1,1,2,2-tetramethyldisilanyl)amine), by following the synthesis method below, the new final product 1-Methoxy-1,1,2,2-tetramethyldisilane is made.

### Example 2

wherein A is an amine and R1 is a methyl, ethyl or any alkyl group. Example 2 exhibits a procedure in which to (N-Ethyl-N-methyl(1,1,2,2-tetramethyldisilanyl)amine) (26.5 g, 0.15 mol) in DCM (dichloromethane) was added a MeOH (methanol) (9.68 g, 0.30 mol) under 30° C. Immediately after injection, some heat is generated in the reactor and some condensation occurs on the inner surface of the flask, without salting out. After overnight of stirring at room temperature, conversion of reaction was determined by analysis of the GC-FID of the reaction mixture, and the distribution of GC-FID was almost 97% one peak with less than 3% impurities. The volatiles were removed in a distillation system at 500 torr and an internal temperature of 60 ° C. The crude was distilled at 40-50 Torr at 40-43° C. to obtain 9.2 g of a target product in 41% yield. The target product was confirmed by 1 H NMR spectroscopy.

In some embodiments the final product can have less than 3% impurities, in other products it can be .less than 2%, in other, less than 1% or even less than that depending on the distillation used for such disilane precursors.

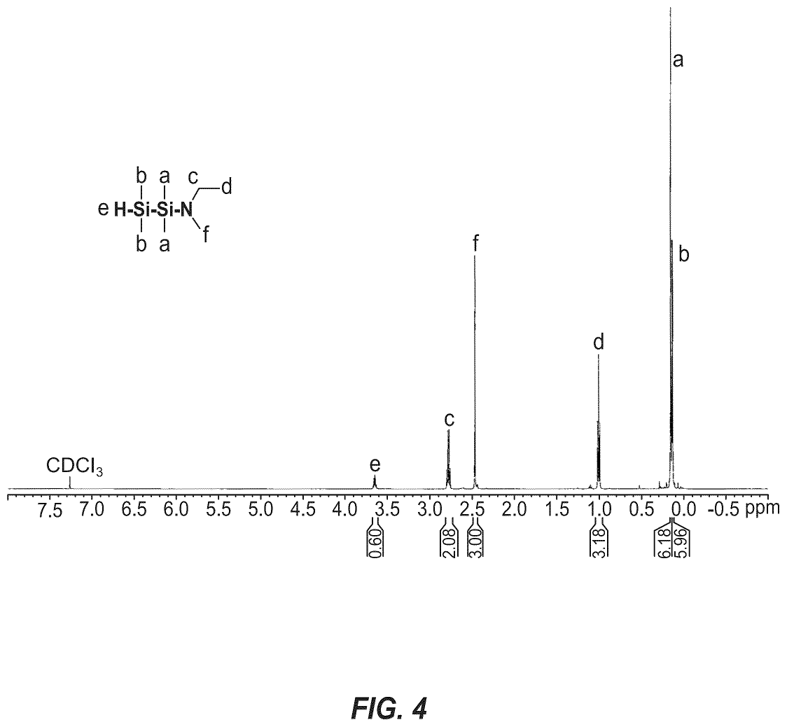

FIG. 4 is a ¹H NMR spectra for N-Ethyl-N-methyl(1,1,2,2-tetramethyldisilanyl)amine, according to some embodiments.

### Aspects

Various Aspects are described below. It is to be understood that any one or more of the features recited in the following Aspect(s) can be combined with any one or more other Aspect(s).

Aspect 1. A precursor comprising:
a compound of the formula:

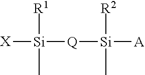

wherein:
X is F, Cl, Br, or I;
R¹ and R² are each independently a hydrogen, an alkyl, an alkenyl, an alkynyl, a cycloalkyl, an aryl, or a benzyl;
A is an amine;
Q is a bond or —SiR³R⁴—,
   wherein R³ and R⁴ are each independently a hydrogen, an alkyl, an alkenyl, an alkynyl, a cycloalkyl, an aryl, or a benzyl.

Aspect 2. The precursor according to Aspect 1, wherein the alkyl is a C₁-C₄ alkyl.

Aspect 3. The precursor according to any one of Aspects 1-2, wherein the alkyl is a C₁-C₄ linear alkyl.

Aspect 4. The precursor according to any one of Aspects 1-3, wherein the alkyl is a C₃-C₄ branched alkyl.

Aspect 5. The precursor according to any one of Aspects 1-4, wherein the cycloalkyl is a C₃-C₆ cycloalkyl.

Aspect 6. The precursor according to any one of Aspects 1-5, wherein the amine is a secondary amine.

Aspect 7. The precursor according to any one of Aspects 1-6, wherein the A is:

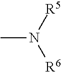

wherein:
R⁵ and R⁶ are each independently a hydrogen, an alkyl, an alkenyl, an alkynyl, a cycloalkyl, an aryl, or a benzyl; or
R⁵ and R⁶ are bonded to obtain a 3-membered cyclic ring to a 6-membered cyclic ring.

Aspect 8. A precursor comprising:
a compound of the formula:

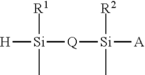

wherein:
R¹ and R² are each independently a hydrogen, an alkyl, an alkenyl, analkynyl, a cycloalkyl, an aryl, or a benzyl;
A is an amine;
Q is a bond or —SiR³R—,
   wherein R³ and R⁴ are each independently a hydrogen, an alkyl, an alkenyl, an alkynyl, a cycloalkyl, an aryl, or a benzyl.

Aspect 9. The precursor according to Aspect 8, wherein the alkyl is a C₁-C₄ alkyl.

Aspect 10. The precursor according to any one of Aspects 8-9, wherein the alkyl is a C₃-C₄ linear alkyl.

Aspect 11. The precursor according to any one of Aspects 8-10, wherein the alkyl is a C₃-C₆ branched alkyl.

Aspect 12. The precursor according to any one of Aspects 8-11, wherein the cycloalkyl is a C3-C6 cycloalkyl.

Aspect 13. The precursor according to any one of Aspects 8-12, wherein the amine is a secondary amine.

Aspect 14. The precursor according to any one of Aspects 8-13, wherein the A is:

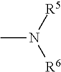

wherein:
   R⁵ and R⁶ are each independently a hydrogen, an alkyl, an alkenyl, an alkynyl, a cycloalkyl, an aryl, or a benzyl; or
   R⁵ and R⁶ are bonded to obtain a 3-membered cyclic ring to a 6-membered cyclic ring.

Aspect 15. The precursor according to any one of Aspects 8-14, wherein

the precursor does not comprise a halide.

Aspect 16. The precursor according to any one of Aspects 8-15, wherein

the precursor is a liquid at 20° C. to 30° C. and at atmospheric pressure.

Aspect 17. A method for forming a precursor, the method comprising:

contacting a dihalide silane compound and an amine in a first solvent to obtain a first reaction product, contacting the first reaction product and a reductant in a second solvent to obtain a second reaction product.

Aspect 18. The method according to Aspect 17, wherein the dihalide

silane compound comprises a compound of the formula:

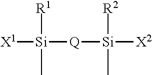

where:
X¹ and X² are each independently F, Cl, Br, or I;
R¹ and R² are each independently a hydrogen, an alkyl, an alkenyl, an alkynyl, a cycloalkyl, an aryl, or a benzyl;
Q is a bond or —SiR³R⁴—,
   wherein R³ and R⁴ are each independently a hydrogen, an alkyl, an alkenyl, an alkynyl, a cycloalkyl, an aryl, or a benzyl.

Aspect 19. The method according to any one of Aspects 17-18, wherein the amine comprises a compound of the formula:

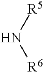

wherein:
R⁵ and R⁶ are each independently a hydrogen, an alkyl, an alkenyl, an alkynyl, a cycloalkyl, an aryl, or a benzyl; or
R⁵ and R⁶ are bonded to obtain a 3-membered cyclic ring to a 6-membered cyclic ring.

Aspect 20. The method according to any one of Aspects 17-19, wherein the first solvent comprises at least one of dichloromethane (CH₂Cl₂), diethyl ether (Et₂O), n-hexane, ethyl acetate (EtOAc), tetrahydrofuran (THF), or any combination thereof.

Aspect 21. The method according to any one of Aspects 17-20, wherein the first reaction product comprises a compound of the formula:

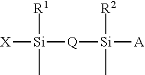

wherein:
X is F, Cl, Br, or I;
R¹ and R² are each independently a hydrogen, an alkyl, an alkenyl, an alkynyl, a cycloalkyl, an aryl, or a benzyl;
A is an amine;
Q is a bond or —SiR³R⁴—,
   wherein R³ and R⁴ are each independently a hydrogen, an alkyl, an alkenyl, an alkynyl, a cycloalkyl, an aryl, or a benzyl.

Aspect 22. The method according to Aspect 21, wherein A is:

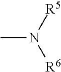

wherein:
R⁵ and R⁶ are each independently a hydrogen, an alkyl, a cycloalkyl, an aryl, or a benzyl; or
R⁵ and R⁶ are bonded to obtain a 3-membered cyclic ring to a 6-membered cyclic ring.

Aspect 23. The method according to any one of Aspects 17-22, wherein reductant comprises at least one of LiAlH₄, NaAlH₄, LiH, DiBAL, LiBH₄, NaBH₄, or any combination thereof.

Aspect 24. The method according to any one of Aspects 17-23, wherein the second solvent comprises at least one of dichloromethane (CH₂Cl₂), diethyl ether (Et₂O), n-hexane, ethyl acetate (EtOAc), tetrahydrofuran (THF), or any combination thereof.

Aspect 25. The method according to any one of Aspects 17-24, wherein the second reaction product comprises a compound of the formula:

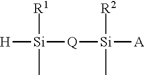

wherein:
R¹ and R² are each independently a hydrogen, an alkyl, an alkenyl, an alkynyl, a cycloalkyl, an aryl, or a benzyl;
A is an amine;
Q is a bond or —SiR³R⁴—,
   wherein R³ and R⁴ are each independently a hydrogen, an alkyl, an alkenyl, an alkynyl, a cycloalkyl, an aryl, or a benzyl.

Aspect 26. The method according to any one of Aspects 17-25, wherein A is an amine of the formula:

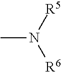

where:
R⁵ and R⁶ are each independently a hydrogen, an alkyl, an alkenyl, an alkynyl, a cycloalkyl, an aryl, or a benzyl; or
R⁵ and R⁶ are linked to obtain a 3-membered cyclic ring to a 6-membered cyclic ring.

Aspect 27. A method of vapor deposition comprising: obtaining a precursor according to any one of Aspects 1-16; vaporizing the precursor to obtain a vaporized precursor; and contacting the vaporized precursor with a substrate, under vapor deposition conditions, to form a silicon-containing film on the substrate.

Aspect 28. The method according to Aspect 27, wherein the vapor deposition conditions include atomic layer deposition conditions.

Aspect 29. The method according to any one of Aspects 27-28, wherein the vapor deposition conditions include chemical vapor deposition conditions.

Aspect 30. The method according to any one of Aspects 27-29, wherein the silicon-containing film comprises at least one of SiO, SiN, SiOC, SiCN, SiOCN, or any combination thereof.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A precursor comprising:
a compound of the formula: 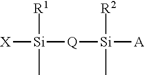
wherein:
X is F, Cl, Br, or I;
R¹ and R² are each independently a hydrogen, an alkyl, an alkenyl, an alkynyl, a cycloalkyl, an aryl, or a benzyl;
A is an amine;
Q is a bond or —SiR³R⁴—,
wherein R³ and R⁴ are each independently a hydrogen, an alkyl, an alkenyl, an alkynyl, a cycloalkyl, an aryl, or a benzyl.

2. The precursor of claim 1, wherein the alkyl is a C₁-C₄ alkyl.

3. The precursor of claim 1, wherein the alkyl is a C₁-C₄ linear alkyl.

4. The precursor of claim 1, wherein the alkyl is a C₃-C₄ branched alkyl.

5. The precursor of claim 1, wherein the cycloalkyl is a C₃-C₆ cycloalkyl.

6. The precursor of claim 1, wherein the amine is a secondary amine.

7. The precursor of claim 1, wherein the A is: 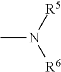
wherein:
R⁵ and R⁶ are each independently a hydrogen, an alkyl, an alkenyl, an alkynyl, a cycloalkyl, an aryl, or a benzyl; or
R⁵ and R⁶ are bonded to obtain a 3-membered cyclic ring to a 6-membered cyclic ring.

8. A precursor comprising:
a compound of the formula: 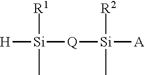
wherein:
R¹ and R² are each independently a hydrogen, an alkyl, an alkenyl, an alkynyl, a cycloalkyl, an aryl, or a benzyl;
A is an amine;
Q is a bond or —SiR³R⁴—,
wherein R³ and R⁴ are each independently a hydrogen, an alkyl, an alkenyl, an alkynyl, a cycloalkyl, an aryl, or a benzyl.

9. The precursor of claim 8, wherein the alkyl is a C₁-C₄ alkyl.

10. The precursor of claim 8, wherein the alkyl is a C₁-C₄ linear alkyl.

11. The precursor of claim 8, wherein the alkyl is a C₃-C₄ branched alkyl.

12. The precursor of claim 8, wherein the cycloalkyl is a C₃-C₆ cycloalkyl.

13. The precursor of claim 8, wherein the amine is a secondary amine.

14. The precursor of claim 8, wherein the A is: 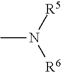
wherein:
R⁵ and R⁶ are each independently a hydrogen, an alkyl, an alkenyl, an alkynyl, a cycloalkyl, an aryl, or a benzyl; or
R⁵ and R⁶ are bonded to obtain a 3-membered cyclic ring to a 6-membered cyclic ring.

15. The precursor of claim 8, wherein the precursor does not comprise a halide.

16. The precursor of claim 8, wherein the precursor is a liquid at 20° C. to 30° C. and at atmospheric pressure.

17. A method for forming a precursor, the method comprising:
contacting a dihalide silane compound and an amine in a first solvent to obtain a first reaction product,
contacting the first reaction product and a reductant in a second solvent to obtain a second reaction product.

18. The method of claim 17, wherein the dihalide silane compound comprises a compound of the formula: 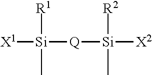
where:
X¹ and X² are each independently F, Cl, Br, or I;
R¹ and R² are each independently a hydrogen, an alkyl, an alkenyl, an alkynyl, a cycloalkyl, an aryl, or a benzyl;
Q is a bond or —SiR³R⁴—,
wherein R³ and R⁴ are each independently a hydrogen, an alkyl, an alkenyl, an alkynyl, a cycloalkyl, an aryl, or a benzyl.

19. The method of claim 17, wherein the amine comprises a compound of the formula: 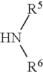
wherein:
R⁵ and R⁶ are each independently a hydrogen, an alkyl, an alkenyl, an alkynyl, a cycloalkyl, an aryl, or a benzyl; or
R⁵ and R⁶ are bonded to obtain a 3-membered cyclic ring to a 6-membered cyclic ring.

20. The method of claim 17, wherein the first solvent comprises at least one of dichloromethane (CH₂Cl₂), diethyl ether (Et₂O), n-hexane, ethyl acetate (EtOAc), tetrahydrofuran (THF), or any combination thereof.
